(19) United States
(12) Patent Application Publication
(10) Pub. No.: US 2025/0226186 A1
(43) Pub. Date: Jul. 10, 2025

(54) HEATERS AND PLASMA GENERATORS FOR GAS ACTIVATION, AND RELATED CHAMBER AND FOR SEMICONDUCTOR MANUFACTURING

(71) Applicant: Applied Materials, Inc., Santa Clara, CA (US)

(72) Inventors: Ala MORADIAN, Sunnyvale, CA (US); Prashanth KOTHNUR, San Jose, CA (US); Saurabh CHOPRA, Santa Clara, CA (US); Ananth Nuggehalli BHOJ, Round Rock, TX (US); Yunho KIM, Milpitas, CA (US); Umesh M. KELKAR, Santa Clara, CA (US)

(21) Appl. No.: 18/407,142

(22) Filed: Jan. 8, 2024

(51) Int. Cl. H01J 37/32; C23C 14/22; C30B 23/08

(52) U.S. Cl. CPC H01J 37/32522; C23C 14/221; C30B 23/08; H01J 37/32119; H01J 37/3244; H01J 2237/3323

(57) ABSTRACT

The present disclosure relates to heaters and plasma generators for gas activation, and related chamber components, methods, and processing chambers for semiconductor manufacturing. The processing chamber includes a chamber body comprising a flow module, a window, one or more heat sources, a substrate support, and a plasma generator. The window and the chamber body at least partially defining a processing volume. The one or more heat sources are operable to heat the processing volume. The substrate support is disposed in the processing volume. The plasma generator disposed at least partially around the processing volume. The window further includes a flange. The flange includes an opaque material. An induction coil is embedded in the opaque material of the flange.

### BACKGROUND

### Field

The present disclosure relates to heaters and plasma generators for gas activation, and related chamber components, methods, and processing chambers for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to heaters and plasma generators for gas activation, and related chamber components, methods, and processing chambers for semiconductor manufacturing.

In one or more embodiments, a processing chamber applicable for semiconductor manufacturing includes a chamber body comprising a flow module, a window, one or more heat sources, a substrate support, and a plasma generator. The window and the chamber body at least partially defining a processing volume. The one or more heat sources are operable to heat the processing volume. The substrate support is disposed in the processing volume. The plasma generator disposed at least partially around the processing volume.

In one or more embodiments, a chamber component applicable for use in semiconductor manufacturing is disclosed. The chamber component includes a flange. The flange includes an opaque material. An induction coil is embedded in the opaque material of the flange.

In one or more embodiments, a processing chamber applicable for use in semiconductor manufacturing includes a source reactor, a substrate support, and a plasma reactor. The substrate support is operable to chuck to a substrate. The plasma reactor includes a lid, a sidewall, an extraction plate, a processing volume defined at least partially by the lid, the sidewall, and the extraction plate; and a plasma generator disposed around the processing volume. The plasma generator is an induction coil.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2A is a schematic side cross-sectional view of a processing chamber, according to one or more embodiments.

FIG. 2B is a schematic side cross-sectional view of a plasma reactor of the processing chamber of FIG. 2A, according to one or more embodiments.

FIG. 3 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heaters and plasma generators for gas activation, and related chamber components, methods, and processing chambers for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

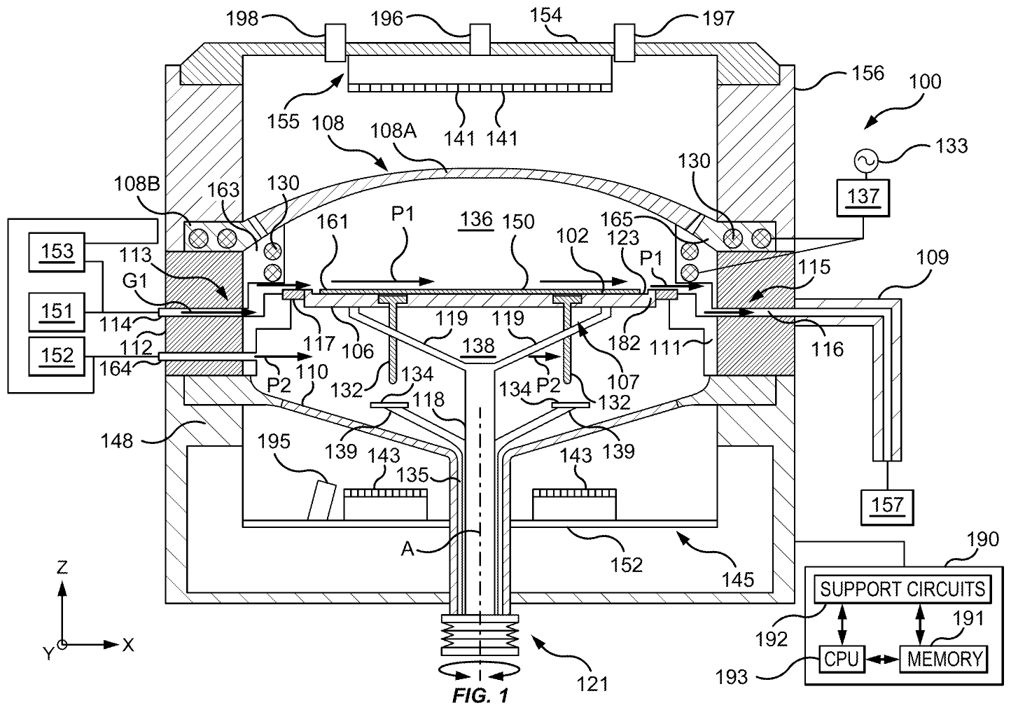

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), and one or more heat sources 141, 143. The one or more heat sources 141, 143 include a plurality of upper heat sources 141 and a plurality of lower heat sources 143. The plurality of upper heat sources 141 and lower heat sources 143 include light emitting diodes (LEDs) or laser diodes (e.g., vertical-cavity surface-emitting laser(s) (VCSEL(s))). The LEDs are operable to spike at a target wavelength. The target wavelength is within a range of about 100 nm to about 1000 μm, such as about 400 nm to 500 nm, such as about 450 nm. In one or more embodiments including LEDs are the upper heat sources 141 and lower heat sources 143, the wavelength of light emitted from the LED may be changed during processing in order to effect the deposition process. For example, a first wavelength of light may be emitted from the LEDs to activate the process gas P1 and a second wavelength of light may be emitted during a processing chamber cleaning process. Further, the LEDs enable more efficient metrology and pyrometry of the substrate 102 and components of the processing chamber 100 (such as the substrate support 106), in part due to the LEDs emitting particular wavelengths of light, as opposed to a broadband spectrum. By emitting more particular wavelengths of light, the amount of noise in the system from other wavelengths of light is reduced, making it easier for sensors (e.g., the pyrometer(s) and other metrology tools) to able to more accurately measure temperature (and other properties) of the substrate 102.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155. The plurality of lower heat sources 143 are disposed between the lower window 110 and a floor 152. The plurality of lower heat sources 143 form a portion of a lower heat source module 145.

The upper window 108 may be an upper dome having a first section 108A and a second section 108B. The first section 108A (e.g., a transparent section) is formed of an energy transmissive material, such as quartz. A second section 108B (e.g., an opaque section or a flange) of the upper window 108 is formed of an opaque material. The opaque material includes opaque quartz (e.g., grey quartz, white quartz, and/or black quartz), graphite, or silicon carbide. In one or more embodiments, the second section 108B is formed of an energy transmissive material, such as quartz. The second section includes a curved inner face 165. The lower window 110 is a lower dome and/or is formed of an energy transmissive material, such as transparent quartz.

A processing volume 136 and a purge volume 138 are formed between the upper window 108 and the lower window 110. The processing volume 136 and the purge volume 138 are part of an internal volume defined at least partially by the upper window 108, the lower window 110, and one or more liners 111, 163. In one or more embodiments, the processing volume 136 is a processing volume. The one or more liners 111, 163 are disposed inwardly of the chamber body.

The internal volume has the substrate support 106 disposed therein. The substrate support 106 includes a top surface 161 on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N2) and/or hydrogen (H₂)). The one or more purge gases P2 supplied using the one or more purge gas sources 162 can include one or more inert gases (such as one or more of argon (Ar), helium (He), and/or nitrogen (N2)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

A plasma generator is disposed around the processing volume 136. In one or more embodiments, the upper liner 163 further includes the plasma generator. In one or more embodiments, the plasma generator includes an induction coil 130. The induction coil 130 is operable to flow radiofrequency (RF) power therethrough to generate a plasma in an inductively coupled plasma (ICP) manner. In one or more embodiments, the induction coil 130 is embedded in the upper liner 163 and/or the upper window 108. The present disclosure contemplates that a plurality of induction coils 130 can be embedded in the upper liner 163 and/or the upper window 108. In one or more embodiments, the upper liner 163 and/or the second section 108B of the upper window 108 includes one or more recesses in which the induction coil 130 is disposed. A plasma can be generated in the processing volume 136 by the induction coil 130. The induction coil 130 is coupled to an RF power generator 133 through a matching network 137. When the induction coil 130 is energized with RF power from the RF power generator 133, a plasma is generated in the processing volume 136. In one or more embodiments, the plasma is generated using the induction coil 130 in an inductively coupled plasma (ICP) manner. In one or more embodiments, RF power is provided to coil 130 at about 1 KW to about 15 KW, such as about 3 KW to about 10 KW. Induction coil(s) 130 may ignite and sustain a plasma in a wide pressure and flow range.

During a deposition operation (e.g., an epitaxial growth operation), the one or more process gases P1 flow through the one or more gas inlets 114, through the one or more gaps, and into the processing volume 136 to flow over the substrate 102. A gas G1 is also flowed into the processing volume 136. The induction coil(s) 130 ignite the gas G1 into the plasma. The induction coil(s) 130 can ionize and disassociate the gas G1 in order to facilitate the deposition onto the substrate 102. For example, the plasma can assist in deposition by breaking down bonds of the one or more process gases P1. The gas G1 used to generate the plasma may include but is not limited to one or more of: hydrogen (H₂), xenon (Xe₂), fluorine (F₂), krypton fluoride (KrF), neon (Ne), and/or any mixtures thereof (such as xenon and/or neon). In one or more embodiments, the gas G1 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the gas G1 includes one or more dopant gases, such as germane, diborane, and/or phosphorous. Other gases are contemplated for the gas G1.

A conductive plate (e.g., an ion filter such as an ion blocker plate) can be disposed in the processing chamber 100. The conductive plate can block ions in the plasma to remove the ions from the plasma. The conductive plate can include silicon carbide (SiC), molybdenum, tungsten, stainless steel, and/or aluminum (such as anodized aluminum).

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. For example, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one or more embodiments, one or more of the sensor devices 195, 196, 197, 198 include a residual gas analyzer, an optical emission spectrometer, an enthalpy probe, a Langmuir probe, Faraday cup, and/or an absorption spectrometer.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, plurality of upper heat sources 141, the plurality of lower heat sources 143, the substrate support 106, and/or the liners 111, 163. As an example, one or more sensor devices 195, 196, 197, 198 can measure temperatures of the plurality of upper heat sources 141, the plurality of lower heat sources 143, and power to the plurality of upper heat sources 141 and the plurality of lower heat sources 143 can be controlled based on the measured temperatures (e.g., using a feedback control). As described the one or more sensor devices can include, for example pyrometers. In one or more embodiments, one or more thermocouples (e.g., proximity thermocouples) are disposed to measure temperatures of one or more components (such as the substrate support 106 and/or the pre-heat ring 117) of the processing chamber 100, and power to the plurality of upper heat sources 141 and the plurality of lower heat sources 143 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the plurality of upper heat sources 141, the plurality of lower heat sources 143, the induction coil(s) 130, the deposition, the cleaning, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump 157.

During processing, in one or more embodiments, the substrate 102 is heated to a target temperature of 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less, such as less than 200 degrees Celsius (for example about 150 degrees Celsius).

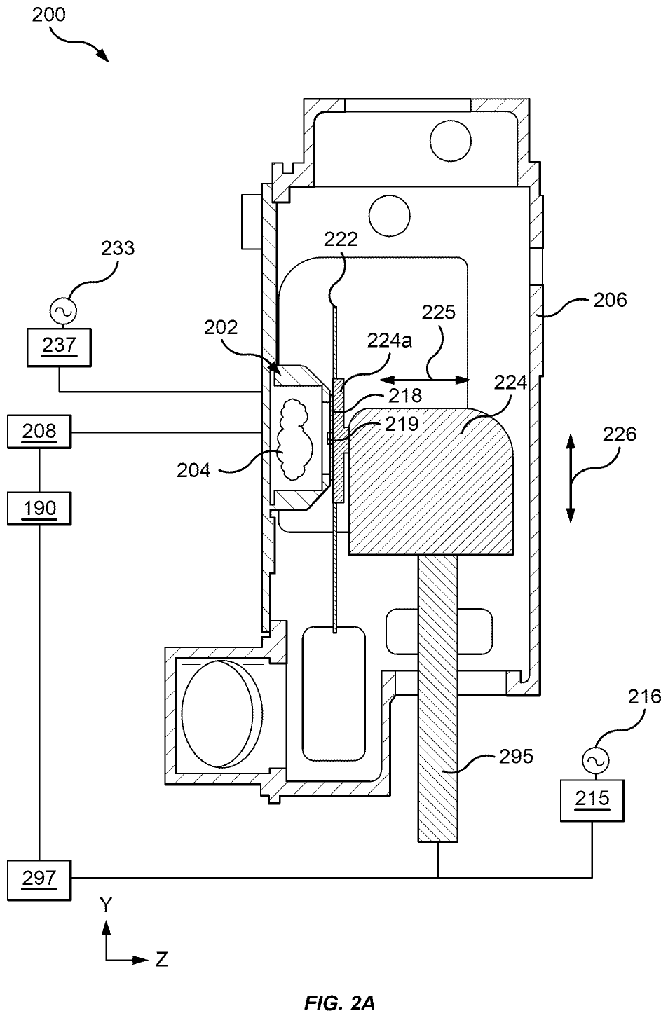

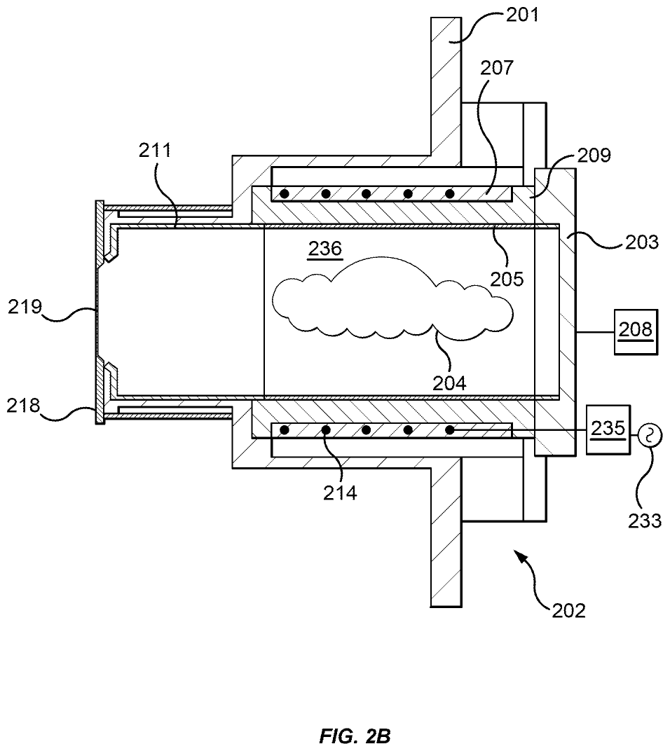

FIG. 2A is a schematic cross-sectional view of a processing chamber 200, according to one or more embodiments. In one or more embodiments, the processing chamber 200 is an ion beam chamber, such as an ion beam etching chamber. The processing chamber is suitable for supplying deposition gases, ions, radicals, dopants, and/or or etchants into a substrate 222 so as to react with the materials from the substrate 222 and to deposit material onto the substrate 222, supply ions, radicals, and/or dopants into the substrate 222, and/or etch the substrate 222. FIG. 2B is a schematic cross-sectional view of a plasma reactor 202 of the processing chamber.

The processing chamber 200 includes the plasma reactor 202 which may supply a plasma 204 through an inner volume. The plasma reactor 202 includes an outer sidewall 201, a lid 203, an upper inner sidewall 205, a dielectric sidewall 209, and a lower inner sidewall 211. The dielectric sidewall 209 is disposed between the plasma source sidewall 207 and the upper inner sidewall 201. The processing volume is defined by the lid 203, the upper inner sidewall 201, and the lower inner sidewall 211. The upper inner sidewall 205 and the lower inner sidewall 211 include a quartz material to withstand elevated temperatures and reduce epitaxial growth contamination. The dielectric sidewall 209 includes a quartz tube. The processing chamber 200 may include at least one gas source 208 to provide a process gas to the plasma reactor 202. The processing chamber 200 may further include a power source 233 through a matching network 237 to generate power to ignite and sustain the plasma 204. The plasma power source may be an inductively-coupled plasma (ICP) source (e.g., an induction coil 214). When the induction coil 214 is energized with RF power from the RF power generator 233, a plasma is generated in the processing volume 236. In one or more embodiments, RF power is provided to coil 130 at about 1 KW to about 15 kW, such as about 3 KW to about 10 KW. Induction coil 214 may ignite and sustain a plasma in a wide pressure and flow range. In one or more embodiments, the induction coil 214 is disposed in a plasma source sidewall 207. The present disclosure contemplates that the plasma source sidewall 207 can be omitted.

The plasma reactor 202 of the processing chamber 200 may be held at ground potential and the substrate 222 and substrate support 224 may be biased positively with respect to ground potential. The substrate 222 is configured to be chucked to the substrate support 224 via a substrate support chuck 224a. In one or more embodiments, the substrate support 224 includes a heater disposed within the substrate support 224 for heating the substrate 222. A bias supply 216 may be configured to generate a voltage difference through a matching network 215 between the plasma reactor 202 and the substrate support 224 disposed in the source reactor 206. The bias supply 216 may bias the plasma reactor 202 positively with respect to ground potential, while the source reactor 206 as well as substrate support 224 is held at ground potential. The processing chamber 200 may be held at ultra high vacuum (e.g., within a range of about 1 mTorr to about 1000 mTorr). When the plasma 204 is present in the plasma reactor 202, and the bias supply 216 biases the plasma reactor 202 positively with respect to ground potential, an ion beam including positive ions may be extracted from the plasma 204. The ion beam including the ions may assist in depositing a film on the substrate 222, etch the substrate 222 (e.g., using molecular beam etching (MBE)), or supply ions into the substrate 222.

The ion beam may be extracted through an aperture 219 in an extraction plate 218, and may be directed to the substrate 222 held on the substrate support 224. In one or more embodiments, the substrate support 224 may be movable with respect to the extraction plate 218. For example, the substrate support 224 may be movable in a direction parallel to the Z-axis of the Cartesian coordinate system shown as indicated by arrow 225. In this manner, a distance between the surface of the substrate 222 and extraction plate 218 may be varied. In one or more embodiments, the substrate support 224 may be configured to scan the substrate 222 relative to the extraction plate 218 in a direction parallel to the plane 262 of the substrate 222. The substrate support 224 may be vertically movable parallel to the Y-axis as indicated by arrow 226.

In one or more embodiments, the gas source 208 of the ion beam etching chamber 200 may supply the one more process gases P1 and/or the gas G1 to the plasma reactor 202 for use in generating the plasma 204 and/or processing the substrate 222. Such feed gases may include the exemplary gases described above in relation to the gas G1 and/or the one or more process gases P1. Ion beams extracted from plasma formed from one or more of the aforementioned noble gases can be effective for etching various substrate materials, including silicon. The gas G1 and/or the one or more process gases P1 can generate a positive pressure in the processing volume 236 so that potentially sputtered atoms from the substrate 222 are blocked from entering the processing volume 236.

The processing chamber 200 does not require a separate showerhead structure in the source reactor 206. Therefore the source reactor 206 may be made smaller, and the ion beam etching chamber 200 may thus have a smaller form factor than chambers using other showerhead gas delivery systems.

The ion beam etching chamber 200 may include the controller 190 operatively connected to the gas source 208 for controlling the delivery of residue removal gas and process gas to the extraction plate 218 in a predetermined manner. The controller 190 may be operatively connected to a drive mechanism 297 that drives the substrate support 224 (via support arm 295) during scanning of the substrate 222, and the controller 190 may be programmed to coordinate the delivery of residue removal gas and process gas to the extraction plate 218, and thus the emission of residue removal gas and process gas, with the position and movement of the substrate support 224 to deliver the residue removal gas and process gas to the substrate 222 in a desired manner as well as receiving the signal/determination/command from an end point detector. In one or more embodiments, the controller 190 may control a rate of the residue removal gas and process gas delivered to the extraction plate 218 for varying the pressures.

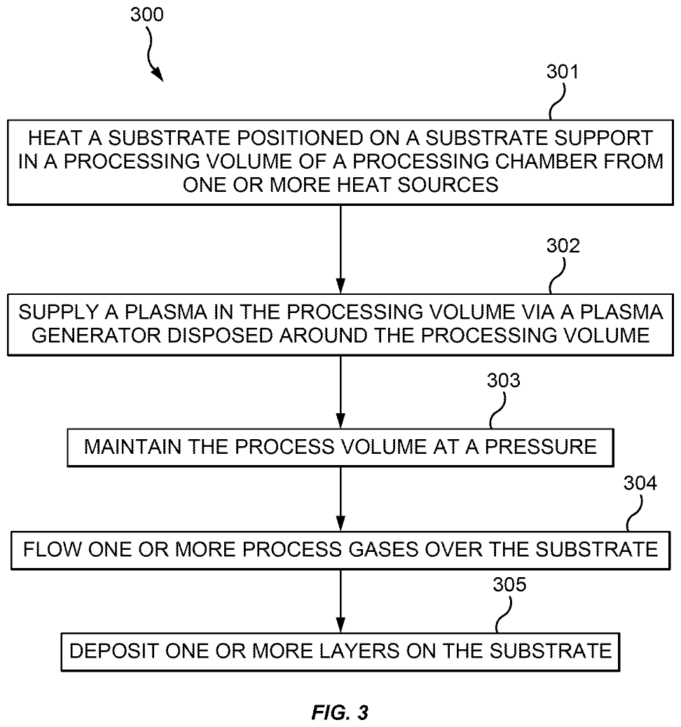

FIG. 3 is a schematic block diagram view of a method 300 of substrate processing applicable for semiconductor manufacturing. Method 300 may be used to process a substrate within processing chamber 100 and/or the processing chamber 200.

At operation 301, a substrate positioned on a substrate support of a processing chamber is heated by one or more heat sources. In one or more embodiments, the one or more heat sources include a plurality of upper heat sources and a plurality of lower heat sources. The upper heat sources are disposed above the substrate. In one or more embodiments, the heat source may be embedded in the substrate support. The heating includes heating the substrate to a target temperature. In one or more embodiments, the target temperature is less than 500 degrees Celsius. In one or more embodiments, the target temperature is 400 degrees Celsius or less.

Operation 302 includes supplying a plasma in a processing volume of the processing chamber via a plasma generator. The plasma generator may include an induction coil. In one or more embodiments, the induction coil is configured to surround the processing volume.

Operation 303 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 m Torr.

Operation 304 includes flowing one or more process gases over the substrate. In one or more embodiments, the plasma of operation 302 is supplied during the flowing of the one or more process gases of operation 304, and the plasma flows over the substrate. In one or more embodiments, the plasma of operation 302 is supplied before or after the flowing of the one or more process gases of operation 304.

Operation 305 includes depositing one or more layers on the substrate. In one or more embodiments, the plasma of operation 302 is supplied during the depositing of operation 305. In one or more embodiments, the plasma of operation 302 is supplied before or after the depositing of operation 305.

Benefits of the present disclosure include reliable gas activation (such as at relatively low processing temperatures); adjustability of gas activation; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for substrate target temperatures less than 500 degrees Celsius, such as target temperatures within a range of 380 degrees to 500 degrees Celsius. For example, the gas can be activated to about 500 degrees Celsius or higher over the substrate when the substrate is at about 400 degrees Celsius.

It is contemplated that one or more aspects disclosed herein may be combined. As an example, one or more aspects, features, components, operations and/or properties of the processing chamber 100; the controller 190; the one or more sensor devices 195, 196, 197, 198; the induction coil 130, the processing chamber 200, and/or the method 300 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body comprising a flow module;
a window, the chamber body and the window at least partially defining a processing volume;
one or more heat sources operable to heat the processing volume;
a substrate support disposed in the processing volume; and
a plasma generator disposed at least partially around the processing volume.

2. The processing chamber of claim 1, wherein the plasma generator comprises an induction coil that is disposed circumferentially around the processing volume.

3. The processing chamber of claim 2, wherein the flow module is operable to supply one or more process gases to the processing volume.

4. The processing chamber of claim 2, further comprising:
a liner comprising one or more flow gaps in communication with one or more gas inlets of the flow module, wherein the plasma generator is embedded in the liner.

5. The processing chamber of claim 2, wherein the window further comprises:
a first section comprising an energy transmissive material; and
a second section comprising an opaque material, wherein the plasma generator is embedded in the second section of the window.

6. The processing volume of claim 3, wherein the one or more process gases comprises silicon (Si), phosphorus (P), germanium (Ge), phosphide (SiP), phospine (PH₃), nitrogen (N2), hydrogen (H₂), or a combination thereof.

7. The processing chamber of claim 1, wherein the one or more heat sources comprise light emitting diodes (LEDs).

8. The processing chamber of claim 7, wherein the LEDs are operable to spike at a target wavelength.

9. The processing chamber of claim 8, wherein the target wavelength is within a range of 400 nm to 500 nm.

10. A chamber component applicable for use in semiconductor manufacturing, the chamber component comprising:
a body comprising a flange, the flange comprising an opaque material; and
an induction coil embedded in the opaque material of the flange.

11. The chamber component of claim 10, further comprising a transparent section formed of an energy transmissive material, wherein the transparent section is radially inwardly of the flange.

12. The chamber component of claim 11, wherein the energy transmissive material comprises transparent quartz, and the opaque material comprises one or more of opaque quartz, graphite, or silicon carbide.

13. The chamber component of claim 10, further comprising one or more flow gaps.

14. The chamber component of claim 10, wherein the curved section comprises a curved inner face.

15. The chamber component of claim 10, wherein the opaque material comprises one or more of opaque quartz, graphite, or silicon carbide.

16. A processing chamber applicable for use in semiconductor manufacturing, comprising:
a source reactor, comprising:
a substrate support operable to chuck a substrate; and
a plasma reactor comprising:
a lid;
a sidewall;
an extraction plate;
a processing volume defined at least partially by the lid, the sidewall, and the extraction plate; and
a plasma generator disposed around the processing volume, wherein the plasma generator is an induction coil.

17. The processing chamber of claim 16, wherein the sidewall comprises:
an outer sidewall;
an upper inner sidewall;
a dielectric sidewall;
a plasma generator sidewall; and
a lower inner sidewall.

18. The processing chamber of claim 17, wherein the induction coil is disposed in the plasma generator sidewall.

19. The processing chamber of claim 16, wherein the substrate support is operable to be biased positively with respect to ground potential and generate a voltage difference between the plasma reactor and the substrate support.

20. The processing chamber of claim 19, wherein the voltage difference between the plasma reactor and the substrate support is configured to generate an ion beam to deposit a film on the substrate.
